(19) United States
(12) Patent Application Publication
(10) Pub. No.: US 2025/0110219 A1
(43) Pub. Date: Apr. 3, 2025

(54) RANGING DEVICE

(71) Applicant: Sony Semiconductor Solutions Corporation, Kanagawa (JP)

(72) Inventor: Akito Sekiya, Kanagawa (JP)

(21) Appl. No.: 18/727,005

(22) PCT Filed: Feb. 10, 2023
(86) PCT No.: PCT/JP2023/004663

§ 371 Date: Jul. 5, 2024

(30) Foreign Application Priority Data
Feb. 22, 2022 (JP) 2022-026073

(51) Int. Cl. G01S 7/4863; G01S 7/4865; G01S 7/497; G01S 17/10

(52) U.S. Cl. CPC G01S 7/4863; G01S 7/4865; G01S 7/497; G01S 17/10

(57) ABSTRACT

Ranging devices that prevent decreases in distance measurement value accuracy are disclosed. In one example, a ranging device includes separate first and second pixels. A first detection unit detects a time of flight (ToF) value based on light reception time of incident light incident on the second pixel, and a control unit controls a bias voltage to be applied to the first pixel and the second pixel on the basis of the ToF value detected by the first detection unit.

### TECHNICAL FIELD

The present disclosure relates to a ranging device.

### BACKGROUND ART

There is a known ranging device using a direct time of flight (dToF) method, in which an object is irradiated with a light pulse signal (Tx pulse signal) and a reflected light pulse signal (Rx pulse signal) from the object is received, and thus a distance to the object is measured on the basis of the time from when the Tx pulse signal is projected to when the Rx pulse signal is received.

For example, a single photon avalanche photo diode (SPAD) is used for reception of the Rx pulse signal. In the SPAD, when an Rx pulse signal is received in a state where a reverse bias voltage larger than a breakdown voltage is applied between an anode and a cathode, a cathode voltage decreases and light emission starts (see Patent Document 1).

### CITATION LIST

### Patent Document

Patent Document 1: Japanese Patent Application Laid-Open No. 2021-56016

### SUMMARY OF THE INVENTION

### Problems to be Solved by the Invention

In a standby state for reception of an Rx pulse signal, the SPAD requires that a reverse bias voltage larger than the breakdown voltage be applied between the anode and the cathode. The SPAD, which is formed using a semiconductor process, changes in electrical characteristics due to manufacturing variations and environmental conditions such as temperature. Specifically, even in a case where the reverse bias voltage of the same voltage level is applied to the SPAD, the degree of decrease in cathode voltage when an Rx pulse signal is received may fluctuate. In a case where the degree of decrease in cathode voltage per unit time of the SPAD is small, the time until the cathode voltage reaches a bottom voltage becomes longer than in a case where the degree of decrease is large, and thus, a distance measurement value becomes longer, and a ranging error occurs.

As described above, when the electrical characteristics of the SPAD fluctuate due to manufacturing variations of the SPAD or the like, the distance measurement value may fluctuate.

Thus, the present disclosure provides a ranging device capable of preventing a decrease in accuracy of a distance measurement value even in a case where electrical characteristics of an SPAD fluctuate.

### Solutions to Problems

In order to solve the problem described above, the present disclosure provides a ranging device including:
a second pixel that is provided separately from a first pixel that performs ranging;
a first detection unit that detects a time of flight (ToF) value based on light reception time of incident light incident on the second pixel; and
a control unit that controls a bias voltage to be applied to the first pixel and the second pixel on the basis of the ToF value detected by the first detection unit.

The first detection unit may detect the ToF value on the basis of a time difference between the light reception time of the incident light incident on the second pixel and time at which a light emitting unit emitted a light signal.

The first pixel may receive a reflected light signal obtained by causing a light signal emitted from a light emitting unit to be reflected by an object, and
the second pixel may directly receive the light signal emitted from the light emitting unit.

The first pixel may have a first photodiode that outputs a voltage signal corresponding to incident light,
the second pixel may have a second photodiode that outputs a voltage signal corresponding to incident light, and
the bias voltage may be a voltage to be supplied to anode pressures or cathodes of the first photodiode and the second photodiode.

The first photodiode and the second photodiode may output the voltage signals from the cathodes in a case where the bias voltage is supplied to the anodes, and output the voltage signals from the anodes in a case where the bias voltage is supplied to the cathodes.

The first detection unit may detect the ToF value based on the light reception time of the incident light by the second photodiode, and
the control unit may control an anode voltage or a cathode voltage of the first photodiode and the second photodiode on the basis of the ToF value detected by the first detection unit.

The first detection unit may detect the ToF value on the basis of a timing at which a voltage level of the voltage signal output from the anode or the cathode of the second photodiode intersects with a predetermined threshold.

The control unit may control the bias voltage to be supplied to the anodes or the cathodes of the first photodiode and the second photodiode in such a way that the ToF value based on the light reception time of the incident light by the second photodiode detected by the first detection unit becomes constant.

The control unit may cause reverse voltages between the anodes and the cathodes of the first photodiode and the second photodiode to become larger in a case where the ToF value detected by the first detection unit is longer than a predetermined reference value.

A time-to-digital converter that generates digital signals corresponding to timings at which the voltage signals are output from the first photodiode and the second photodiode, and
a histogram generator that generates a histogram representing a frequency distribution of the light reception time of the incident light on the basis of the digital signal
may be further included, and
the first detection unit may detect a peak position of the histogram based on the incident light of the second photodiode.

A distance measurement unit that measures a distance to an object on the basis of the peak position of the histogram based on the incident light of the first photodiode may be further included.

A third pixel that is provided separately from the first pixel and the second pixel, and
a voltage monitoring unit that monitors a breakdown voltage of a third photodiode in the third pixel
may be further included, and
the control unit may control an anode voltage or a cathode voltage of the first photodiode, the second photodiode, and the third photodiode on the basis of the ToF value detected by the first detection unit and the breakdown voltage monitored by the voltage monitoring unit.

A temperature measuring instrument that measures an ambient temperature may be further included, and
the control unit may control an anode voltage or a cathode voltage of the first photodiode and the second photodiode on the basis of the ToF value detected by the first detection unit and the temperature measured by the temperature measuring instrument.

A third pixel that is provided separately from the first pixel and the second pixel,
a voltage monitoring unit that monitors a breakdown voltage of a third photodiode in the third pixel, and
a temperature measuring instrument that measures an ambient temperature
may be further included, and
the control unit may have:
a first control unit that controls the bias voltage to be supplied to the anodes or the cathodes of the first photodiode and the second photodiode on the basis of the breakdown voltage monitored by the voltage monitoring unit and the temperature measured by the temperature measuring instrument; and
a second control unit that controls the bias voltage to be supplied to the anodes or the cathodes of the first photodiode and the second photodiode on the basis of the ToF value detected by the first detection unit after the controlling by the first control unit.

A second detection unit that detects the number of light receiving pulses per unit time in the first pixel may be further included, and
the control unit may control an anode voltage or a cathode voltage of the first photodiode and the second photodiode on the basis of the ToF value detected by the first detection unit and the number of light receiving pulses per unit time detected by the second detection unit.

The control unit may cause reverse voltages between the anodes and the cathodes of the first photodiode and the second photodiode to become smaller in a case where the number of light receiving pulses detected by the second detection unit is larger than a predetermined reference number of pulses.

A light emitting unit that emits a light signal may be further included, and
the first photodiode in the first pixel may receive the incident light based on a reflected light signal from an object irradiated with the light signal.

The second pixel may be arranged away from the first pixel, and
a light shielding member may be included, the light shielding member being arranged around the second photodiode in such a way that the light signal to be incident on the second photodiode is not incident on the first photodiode.

A pixel array unit that has a plurality of pixels, each of the pixels having a photodiode, may be further included,
some of the pixels in the pixel array unit may be used as the first pixel,
at least some of the pixels other than the some of the pixels in the pixel array unit may be used as the second pixel, and
a light shielding member may be included, the light shielding member being arranged along a boundary region between the first pixel and the second pixel in the pixel array unit, and being arranged around the second photodiode in such a way that the light signal to be incident on the second photodiode is not incident on the first photodiode.

The light signal emitted from the light emitting unit may be radiated in a direction toward the object, and may be also radiated in a direction toward the second pixel.

### BRIEF DESCRIPTION OF DRAWINGS

FIG. 1 is a block diagram illustrating a schematic configuration of a ranging system including a ranging device according to a first embodiment.

FIG. 2 is a schematic perspective view of a laminate in which the ranging device in FIG. 1 is implemented.

FIG. 3A is a block diagram illustrating a first arrangement example of the ranging device, a voltage control unit, and a light emitting unit.

FIG. 3B is a block diagram illustrating a second arrangement example of the ranging device, the voltage control unit, and the light emitting unit.

FIG. 3C is a block diagram illustrating a third arrangement example of the ranging device, the voltage control unit, and the light emitting unit.

FIG. 4A is a diagram illustrating a first example of a light shielding member.

FIG. 4B is a diagram illustrating a second example of the light shielding member.

FIG. 5 is a flowchart illustrating an example of a processing operation of the ranging device in FIG. 1 and the voltage control unit.

FIG. 6 is a diagram illustrating light reception time of a Tx pulse signal in an SPAD in a second pixel, and a cathode voltage waveform of the SPAD.

FIG. 7 is a detailed block diagram of a main portion in the ranging device according to the first embodiment.

FIG. 8 is a detailed block diagram of a main portion in a ranging device according to a second embodiment.

FIG. 9 is a block diagram illustrating an internal configuration of a VBD monitor.

FIG. 10 is a flowchart illustrating a processing operation of the ranging device according to the second embodiment.

FIG. 11 is a detailed block diagram of a main portion in the ranging device according to the first embodiment.

FIG. 12 is a block diagram in which a connection relationship between an anode and a cathode of the SPAD in FIG. 7 is reversed.

FIG. 13 is a block diagram illustrating an example of a schematic configuration of a vehicle control system.

FIG. 14 is an explanatory diagram illustrating an example of installation positions of an outside-vehicle information detecting section and an imaging section.

### MODE FOR CARRYING OUT THE INVENTION

Embodiments of a ranging device will be described below with reference to the drawings. Although main components of the ranging device will be mainly described below, the ranging device may have components and functions that are not illustrated or described. The following description does not exclude components and functions that are not illustrated or described.

### First Embodiment

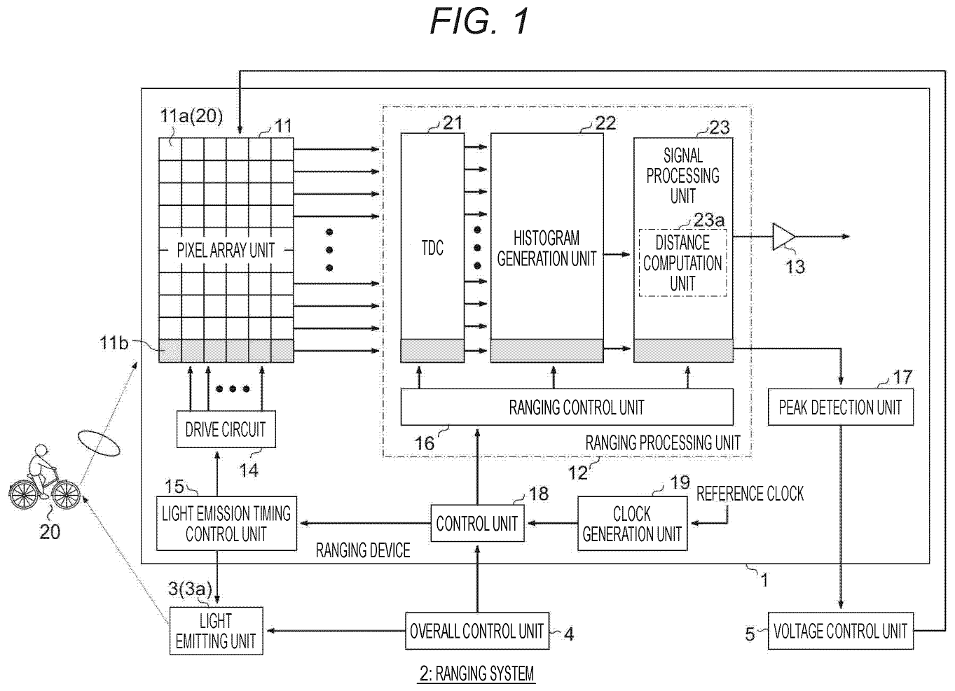

FIG. 1 is a block diagram illustrating a schematic configuration of a ranging system 2 including a ranging device 1 according to a first embodiment. The ranging system 2 in FIG. 1 includes the ranging device 1, a light emitting unit 3, an overall control unit 4, and a voltage control unit 5.

The light emitting unit 3 has a plurality of light emitting elements 3a arranged in a one-dimensional or two-dimensional direction. The plurality of light emitting elements 3a repeatedly emit light pulse signals (Tx pulse signals) at predetermined time intervals. The light emitting unit 3 can cause the light signals emitted from the plurality of light emitting elements 3a to scan across a predetermined two-dimensional space. As for a specific technique for the scanning with the light signals, any technique can be used. The overall control unit 4 controls the light emitting unit 3 and the ranging device 1. At least one of the light emitting unit 3 or the overall control unit 4 can be integrated into the ranging device 1.

The ranging device 1 has a pixel array unit 11, a ranging processing unit 12, an output unit 13, a drive circuit 14, a light emission timing control unit 15, a ranging control unit 16, a peak detection unit (first detection unit) 17, a control unit 18, and a clock generation unit 19.

The pixel array unit 11 has a plurality of pixels (first pixel) 11a arranged in a one-dimensional or two-dimensional direction. Each pixel 11a has a light receiving element 20. The light receiving element 20 is, for example, an SPAD 20. An example in which each pixel 11a has the SPAD 20 will be mainly described below. Each pixel 11a may have a quenching circuit (not illustrated). In an initial state, the quenching circuit supplies, between an anode and a cathode of the SPAD 20, a reverse bias voltage of a potential difference that exceeds a breakdown voltage. When the SPAD 20 detects a photon and the potential difference between the anode and the cathode decreases, the drive circuit 14 supplies a reverse bias voltage to the SPAD 20 via a corresponding quenching circuit to prepare for detection of the next reflected light pulse signal (Rx pulse signal).

By controlling an anode voltage of the SPAD 20, it is possible to control sensitivity of the SPAD 20. In the present embodiment, the anode voltage of the SPAD 20 is controlled by a bias voltage output from the voltage control unit 5, and thus the sensitivity of the SPAD 20 is controlled. Note that, as described later, a configuration may be adopted in which the sensitivity of the SPAD 20 is controlled by controlling a cathode voltage of the SPAD 20.

The ranging device 1 in FIG. 1 has a second pixel 11b used for bias voltage control, in addition to the first pixel 11a that performs ranging. The pixel array unit 11 has the first pixel 11a. The second pixel 11b may be provided in the pixel array unit 11, or may be provided separately from the pixel array unit 11. Each of the first pixel 11a and the second pixel 11b is constituted by one or more pixels. As described later, the first pixel 11a receives an Rx pulse signal, whereas the second pixel 11b receives a Tx pulse signal.

The ranging processing unit 12 has a TDC 21, a histogram generation unit 22, and a signal processing unit 23.

The TDC 21 generates, with predetermined temporal resolution, a digital signal corresponding to light reception time of an Rx pulse signal or a Tx pulse signal received by the SPAD 20. By controlling the temporal resolution of the TDC 21, it is possible to perform variable control of a ranging accuracy. The TDC 21 is provided for each of the first pixel 11a and the second pixel 11b.

On the basis of the digital signal generated by the TDC 21, the histogram generation unit 22 generates a histogram of bin width corresponding to the temporal resolution of the TDC 21. The bin width is the width of each frequency unit constituting the histogram. As the temporal resolution of the TDC 21 is higher, the bin width can be narrower, and it is possible to obtain a histogram in which the time and frequency of reception of the Rx pulse signal is reflected with higher accuracy.

The signal processing unit 23 has a distance computation unit 23a. The distance computation unit 23a computes the distance to an object by, for example, computing the barycentric position of the Rx pulse signal on the basis of the histogram. Information regarding the distance to the object is output to the outside of the ranging device 1 (e.g., a host computer (not illustrated)) via the output unit 13.

On the basis of a signal from the signal processing unit 23, the peak detection unit 17 detects a ToF value based on light reception time of a Tx pulse signal incident on the second pixel 11b. The ToF value is a value based on a time difference between the light reception time of the Tx pulse signal in the second pixel 11b and light emission time of the Tx pulse signal, and is a value based on a peak position of a histogram generated by the histogram generation unit 22. In a stricter sense, the light reception time of the Tx pulse signal is the time at which the cathode voltage of the SPAD 20 in the second pixel 11b falls below threshold voltage of an inverter in the subsequent stage.

The voltage control unit 5 controls the bias voltage to be applied to the first pixel 11a and the second pixel 11b in the pixel array unit 11 on the basis of the ToF value based on the light reception time of the Tx pulse signal detected by the peak detection unit 17. More specifically, the voltage control unit 5 controls the anode voltage of each SPAD 20 in the first pixel 11a and the second pixel 11b so that the ToF value based on the light reception time of the Tx pulse signal received by the SPAD 20 in the second pixel 11b to be detected by the peak detection unit 17 becomes constant.

Although the voltage control unit 5 is illustrated separately from the ranging device 1 in FIG. 1, the ranging device 1 can incorporate the voltage control unit 5. As described above, for example, the bias voltage is applied to the anode of each SPAD 20 in the first pixel 11a and the second pixel 11b.

The clock generation unit 19 generates a clock signal for synchronizing each unit of the ranging device 1 in synchronization with a reference clock signal input from the outside. The control unit 18 controls the ranging control unit 16 and the light emission timing control unit 15 in synchronization with the clock signal. The ranging control unit 16 controls the TDC 21, the histogram generation unit 22, and the signal processing unit 23 in the ranging processing unit 12. The light emission timing control unit 15 controls a timing at which the light emitting unit 3 emits a Tx pulse signal, and also controls the drive circuit 14. The drive circuit 14 performs quench control or the like to restore the cathode voltage to the original voltage when the SPAD 20 of each pixel 11a in the pixel array unit 11 detects light and the cathode voltage lowers.

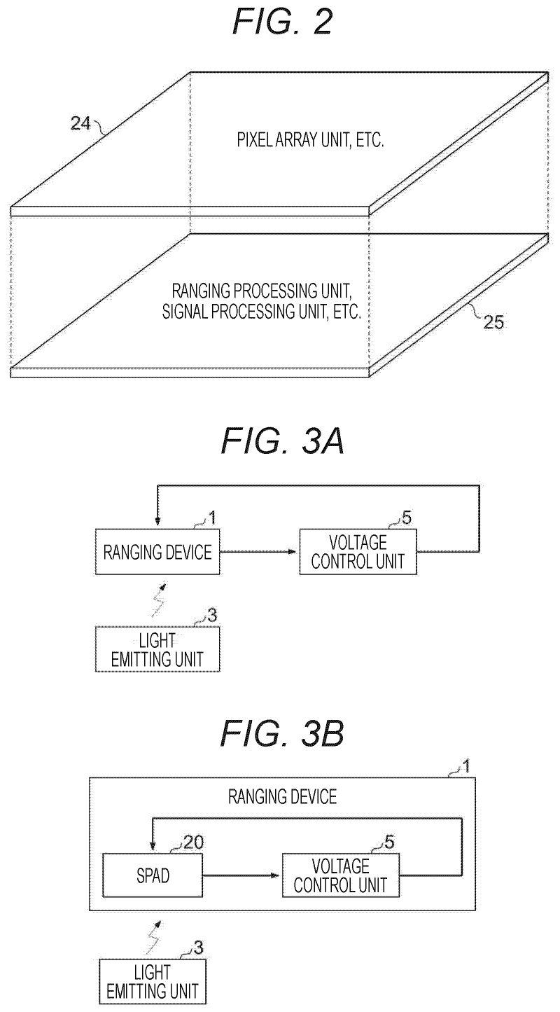

The ranging device 1 in FIG. 1 can be constituted by a laminate in which a plurality of chips are laminated. FIG. 2 is a schematic perspective view of a laminate in which the ranging device 1 in FIG. 1 is implemented. The laminate in FIG. 2 has a first chip 24 and a second chip 25 laminated on the first chip 24. On the first chip 24, the pixel array unit 11 in FIG. 1 is mainly arranged. At least some of components other than the pixel array unit 11 in the ranging device 1 in FIG. 1 are arranged on the second chip 25. The first chip 24 and the second chip 25 are bonded by Cu—Cu bonding, a via, a bump, or the like. It is also possible that some of the components other than the pixel array unit 11 in the ranging device 1 in FIG. 1 are arranged on the first chip 24, and the rest of the components are arranged on the second chip 25. Alternatively, all the components other than the pixel array unit 11 in the ranging device 1 in FIG. 1 may be arranged on the second chip 25, Furthermore, at least one of the light emitting unit 3, the overall control unit 4, or the voltage control unit 5 in FIG. 1 may be arranged on the first chip 24 or the second chip 25. Moreover, the ranging device 1 in FIG. 1 may be constituted by a laminate in which three or more chips are laminated.

As a specific arrangement of the ranging device 1, the voltage control unit 5, and the light emitting unit 3 in FIG. 1, several arrangement examples can be considered. Three representative arrangement examples will be described below. Note that an arrangement example other than the following three arrangement examples may be adopted.

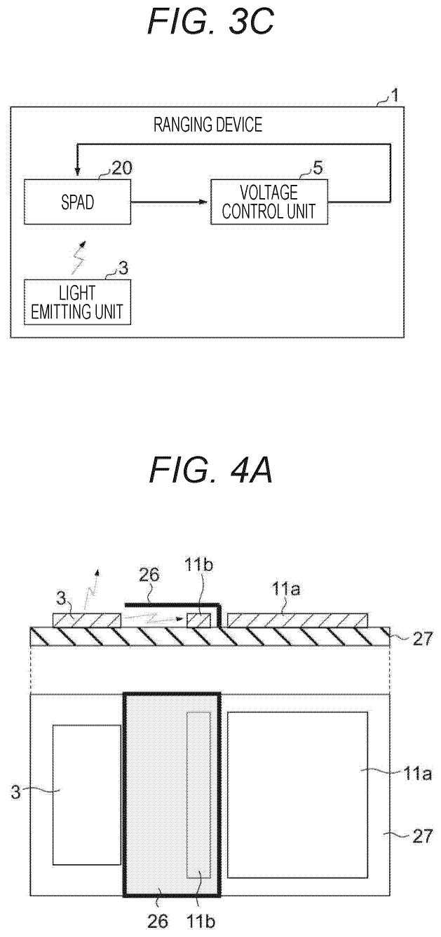

FIG. 3A is a block diagram illustrating a first arrangement example of the ranging device 1, the voltage control unit 5, and the light emitting unit 3. As illustrated in FIG. 3A, in the first arrangement example, the ranging device 1, the voltage control unit 5, and the light emitting unit 3 are individually arranged on different chips. The second pixel 11b in the ranging device 1 directly receives a Tx pulse signal from the light emitting unit 3, and transmits, to the voltage control unit 5, information regarding the ToF value based on the light reception time of the Tx pulse signal. The voltage control unit 5 generates a bias voltage corresponding to the ToF value based on the light reception time of the Tx pulse signal in the second pixel 11b, and transmits the bias voltage to the ranging device 1. In the SPAD 20 of each pixel 11a of the pixel array unit 11 in the ranging device 1, the anode voltage is controlled in accordance with the bias voltage. The three chips in FIG. 3A may be laminated in the vertical direction, or may be arranged on the same support substrate.

FIG. 3B is a block diagram illustrating a second arrangement example of the ranging device 1, the voltage control unit 5, and the light emitting unit 3. As illustrated in FIG. 3B, in the second arrangement example, the ranging device 1 and the voltage control unit 5 are arranged on the same chip, and the light emitting unit 3 is arranged on another chip. These two chips may be laminated in the vertical direction, or may be arranged on the same support substrate. In the second arrangement example, the number of chips can be reduced as compared with the first arrangement example, and manufacturing of the ranging system 2 becomes easier than in the first arrangement example.

FIG. 3C is a block diagram illustrating a third arrangement example of the ranging device 1, the voltage control unit 5, and the light emitting unit 3. As illustrated in FIG. 3C, in the third arrangement example, the ranging device 1, the voltage control unit 5, and the light emitting unit 3 are arranged on the same chip. In the third arrangement example, since the ranging system 2 can be implemented with one chip, the cost of constructing the ranging system 2 can be suppressed, but the difficulty of the process of manufacturing the chip increases.

In the ranging device 1 according to the present embodiment, a Tx pulse signal emitted by the light emitting unit 3 is directly received by the second pixel 11b, and the bias voltage of each pixel 11a in the pixel array unit 11 is controlled. On the other hand, the first pixel 11a receives an Rx pulse signal from an object. Thus, it is necessary to take a countermeasure so that Tx pulse signals are not incident on the first pixel 11a. As a specific countermeasure, it is conceivable to provide a light shielding member.

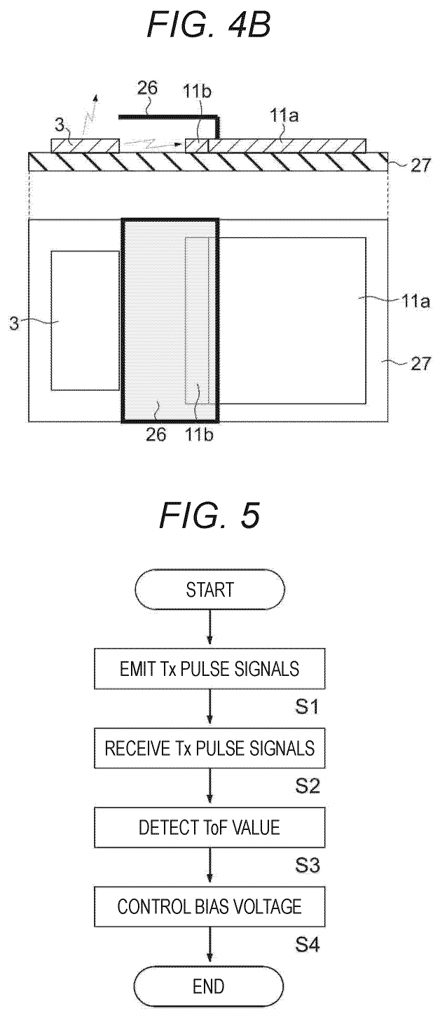

FIG. 4A is a diagram illustrating a first example of a light shielding member 26, and illustrates a side view and a plan view of the light emitting unit 3, the first pixel 11a, and the second pixel 11b. In the first example, the second pixel 11b is arranged separately from the pixel array unit 11 having the first pixel 11a, and the light shielding member 26 is arranged around the second pixel 11b. Tx pulse signals emitted from the light emitting unit 3 travel in a plurality of directions. Specifically, some of the Tx pulse signals emitted from the light emitting unit 3 travel in a direction toward the object, and at least some of the rest of the Tx pulse signals travel in a direction toward the second pixel 11b. Since the light shielding member 26 can prevent incidence of Tx pulse signals on the first pixel 11a, there is no possibility that the ranging accuracy decreases.

FIG. 4B is a diagram illustrating a second example of the light shielding member 26, and illustrates a side view and a plan view of the light emitting unit 3, the first pixel 11a, and the second pixel 11b. In the second example, the first pixel 11a and the second pixel 11b are arranged in the pixel array unit 11, and the light shielding member 26 is arranged around the second pixel 11b. The second pixel 11b is arranged at the end portion of the pixel array unit 11, and the light shielding member 26 is arranged in the boundary region between the second pixel 11b and the first pixel 11a, so that Tx pulse signals are not incident on the first pixel 11a.

Note that FIGS. 4A and 4B illustrate examples in which the light emitting unit 3, the first pixel 11a, and the second pixel 11b are arranged on the same support substrate 27, and it is also possible to separate, for example, the support substrate 27 on which the light emitting unit 3 is arranged and the support substrate 27 on which the first pixel 11a and the second pixel 11b are arranged.

FIG. 5 is a flowchart illustrating an example of a processing operation of the ranging device 1 and the voltage control unit 5 in FIG. 1. First, in accordance with an instruction from the light emission timing control unit 15, the light emitting unit 3 periodically emits Tx pulse signals (step S1). The interval at which the Tx pulse signals are emitted is set to a length equal to or longer than the time required for Rx pulse signals corresponding to the Tx pulse signals to be received by the pixel array unit 11.

As described above, the Tx pulse signals travel in various directions, and some of them are received by the second pixel 11b (step S2). The second pixel 11b outputs a voltage signal corresponding to a Tx pulse signal. More specifically, the cathode voltage of the SPAD 20 in the second pixel 11b decreases when a Tx pulse signal is received. In the present embodiment, the cathode voltage of the SPAD 20 in the second pixel 11b is used as a voltage signal corresponding to the Tx pulse signal.

The peak detection unit 17 detects the ToF value based on the light reception time of the Tx pulse signal on the basis of the voltage signal output from the second pixel 11b (step S3). The peak detection unit 17 may be integrated into the signal processing unit 23 in FIG. 1, and the signal processing unit 23 may detect the ToF value. The light reception time of the Tx pulse signal is the time at which the cathode voltage of the SPAD 20 in the second pixel 11b falls below the threshold voltage of the inverter in the subsequent stage.

Next, the voltage control unit 5 compares the ToF value based on the light reception time of the Tx pulse signal with a reference value prepared in advance, and controls the bias voltage of each pixel 11a in the pixel array unit 11 on the basis of a result of the comparison (step S4). More specifically, in a case where the ToF value based on the light reception time of the Tx pulse signal is longer than the reference value, the bias voltage is controlled so that the anode voltage of the SPAD 20 becomes lower. That is, in a case where the light reception time of the Tx pulse signal is later than expected, a larger reverse bias voltage is applied between the anode and the cathode of the SPAD 20 so that the sensitivity of the SPAD 20 is improved.

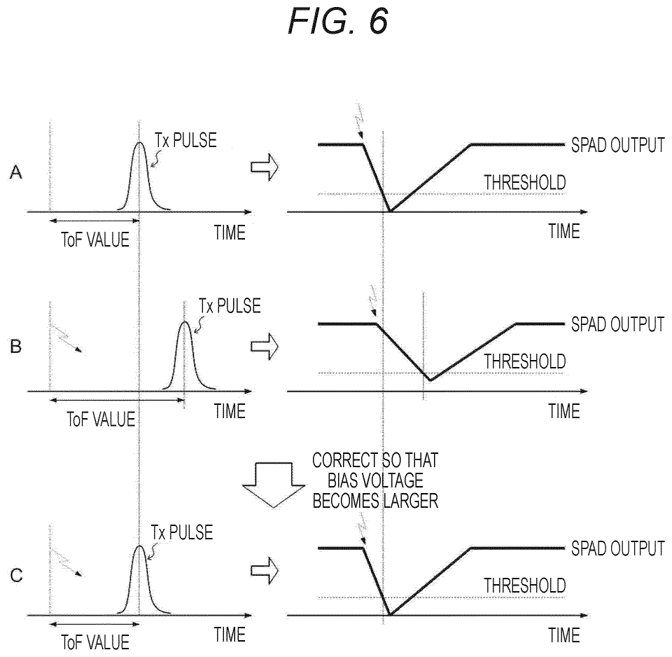

FIG. 6 is a diagram illustrating the light reception time of the Tx pulse signal in the SPAD 20 in the second pixel 11b, and a cathode voltage waveform of the SPAD 20. FIG. 6A illustrates a case where the light reception time of the Tx pulse signal in the second pixel 11b is as expected, and FIG. 6B illustrates a case where the light reception time of the Tx pulse signal in the second pixel 11b is later than expected. FIG. 6C is a diagram illustrating a state after the bias voltage has been controlled in the case of FIG. 6B.

As illustrated in FIG. 6B, in a case where the light reception time of the Tx pulse signal is later than expected, the degree of decrease in cathode voltage of the SPAD 20 in the second pixel 11b becomes milder than expected. Thus, it takes more time than expected until the cathode voltage falls below the threshold voltage. The TDC 21 generates a digital signal on the basis of the time at which the cathode voltage of the SPAD 20 intersects with the threshold voltage. Thus, the ToF value becomes larger as the time at which the cathode voltage intersects with the threshold voltage is later.

Thus, the voltage control unit 5 controls the bias voltage to lower the anode voltage of the SPAD 20 so that the reverse bias voltage of the SPAD 20 becomes larger. With this arrangement, as illustrated in FIG. 6C, the cathode voltage of the SPAD 20 in the second pixel 11b decreases more quickly when the Tx pulse signal is received, the time at which the cathode voltage falls below the threshold voltage becomes earlier, and the ToF value becomes smaller so as to be made comparable to the ToF value in FIG. 6A.

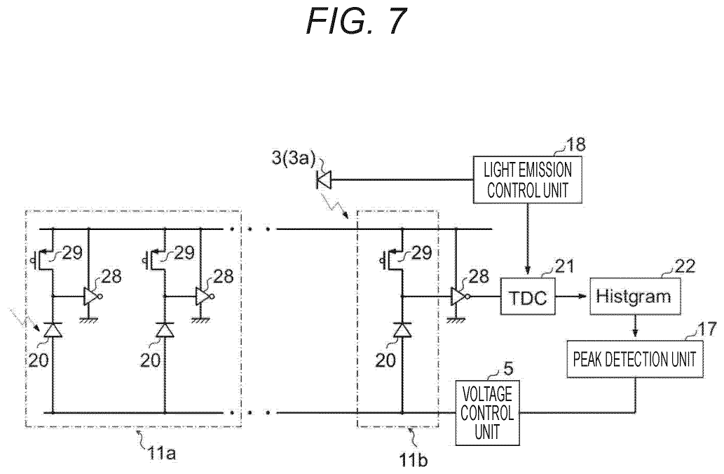

FIG. 7 is a detailed block diagram of a main portion in the ranging device 1 according to the first embodiment. In FIG. 7, the voltage control unit 5 is illustrated as a part of the ranging device 1. The first pixel 11a in the pixel array unit 11 receives an Rx pulse signal reflected by an object. The number of pixels in the first pixel 11a is optional. The cathode of the SPAD 20 in the first pixel 11a is connected with an inverter 28. When the SPAD 20 in the first pixel 11a receives an Rx pulse signal, the cathode voltage decreases, and when the cathode voltage falls below threshold voltage of the inverter 28, an output signal of the inverter 28 transitions from a low level to a high level. The output signal of the inverter 28 is input to the TDC 21, and a digital signal is generated. Although the TDC 21 and the histogram generation unit 22 corresponding to the first pixel 11a are omitted in FIG. 7, when the SPAD 20 in the first pixel 11a receives an Rx pulse signal, the TDC 21 generates a digital signal corresponding to the light reception time of the Rx pulse signal, and the histogram generation unit 22 generates a histogram of bin width corresponding to the temporal resolution of the digital signal.

Furthermore, the second pixel 11b, which is provided in the pixel array unit 11 or provided separately from the pixel array unit 11, directly receives a Tx pulse signal emitted by the light emitting unit 3. The cathode of the SPAD 20 in the second pixel 11b is also connected with an inverter 28. When the SPAD 20 in the second pixel 11b receives a Tx pulse signal, the cathode voltage of the SPAD 20 decreases. When the cathode voltage falls below the threshold voltage of the inverter 28, the output of the inverter 28 transitions from a low level to a high level. The output signal of the inverter 28 is input to the TDC 21, and a digital signal corresponding to the time at which the cathode voltage of the SPAD 20 falls below the threshold voltage of the inverter 28 is generated. The histogram generation unit 22 generates a histogram of bin width corresponding to the temporal resolution of the digital signal generated by the TDC 21. The peak detection unit 17 detects the peak position on the basis of the histogram. The peak position detected by the peak detection unit 17 is a ToF value based on the light reception time of an Rx pulse signal in the second pixel 11b. The voltage control unit 5 compares the ToF value with a reference value, and controls the bias voltage in accordance with a result of the comparison.

As illustrated in FIG. 7, the anode of each SPAD 20 in the first pixel 11a and the anode of each SPAD 20 in the second pixel 11b are both connected to an output node of the voltage control unit 5. Thus, the anode voltage of each SPAD 20 in the first pixel 11a and the second pixel 11b can be controlled by the bias voltage output from the voltage control unit 5.

More specifically, the reverse bias voltage between the anode and the cathode of each SPAD 20 becomes larger as the bias voltage output from the voltage control unit 5 becomes lower. As the reverse bias voltage becomes larger, the sensitivity of each SPAD 20 is improved more and the degree of decrease in cathode voltage at the time of reception of a Tx pulse signal or an Rx pulse signal becomes larger, and thus the cathode voltage falls below the threshold voltage more quickly.

A constant current source 29 constituted by a PMOS transistor is connected between the cathode of each SPAD 20 in the first pixel 11a and the second pixel 11b and a power supply voltage node. The circuit configuration of the constant current source 29 is optional.

As described above, in the first embodiment, the second pixel 11b is provided separately from the first pixel 11a for ranging. The second pixel 11b is used to detect the ToF value when the SPAD 20 receives a Tx pulse signal. In the SPAD 20, the ToF value fluctuates due to manufacturing variations or the like, and a ranging error occurs.

The ranging device 1 according to the present embodiment causes the second pixel 11b to directly receive a Tx pulse signal. The peak detection unit 17 obtains a ToF value corresponding to the time at which the cathode voltage of the SPAD 20 in the second pixel 11b falls below the threshold voltage. The voltage control unit 5 compares the ToF value with a reference value, and controls the bias voltage on the basis of a result of the comparison. The bias voltage output from the voltage control unit 5 is supplied to the anode of each SPAD 20 in the first pixel 11a and the second pixel 11b. With this arrangement, in a case where the ToF value is larger than the reference value, the reverse bias voltage between the anode and the cathode of each SPAD 20 in the first pixel 11a and the second pixel 11b is made larger. Thus, the degree of decrease in cathode voltage when the SPAD 20 receives an Rx pulse signal or a Tx pulse signal can be made larger, and the ToF value can be made smaller so as to be closer to the reference value.

As described above, in the first embodiment, the ToF value when the SPAD 20 in the second pixel 11b receives a Tx pulse signal can be made constant, and ranging errors can be reduced.

### Second Embodiment

In the first embodiment, an example in which the degree of decrease in cathode voltage of the SPAD 20 is controlled by the bias voltage has been described, but the breakdown voltage of the SPAD 20 may fluctuate depending on the process of manufacturing, the temperature, and the like. Thus, in a second embodiment, in addition to the functions of the first embodiment, at least one of a function of monitoring the breakdown voltage of the SPAD 20 and controlling the bias voltage or a function of controlling the bias voltage in accordance with the temperature is combined.

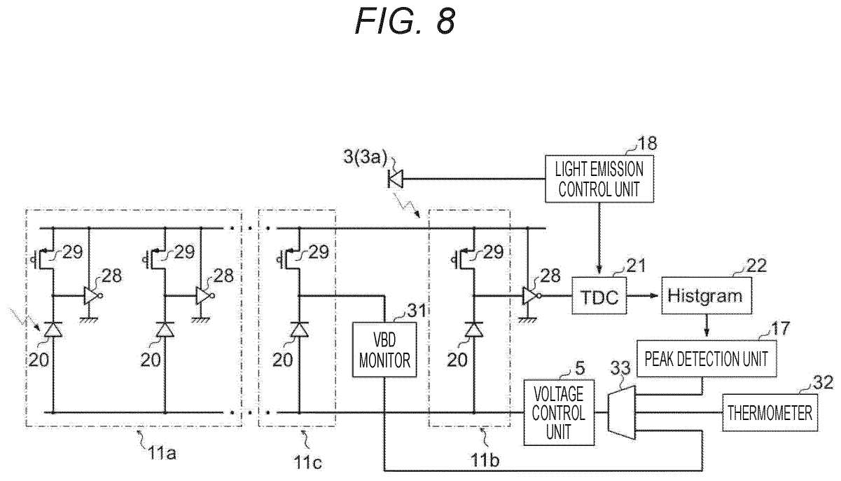

FIG. 8 is a detailed block diagram of a main portion in a ranging device 1 according to the second embodiment. The ranging device 1 in FIG. 8 includes a VBD monitor (voltage monitoring unit) 31, a thermometer (temperature measuring instrument) 32, and a selector 33, in addition to the configuration in FIG. 7.

The ranging device 1 in FIG. 8 has a third pixel 11c, separately from a first pixel 11a for ranging and a second pixel 11b for ToF value detection. The third pixel 11c may be provided in a pixel array unit 11, or may be provided separately from the pixel array unit 11. The third pixel 11c is not used for ranging.

The VBD monitor 31 measures the cathode voltage of an SPAD 20 in the third pixel 11c, and detects the breakdown voltage of the SPAD 20 on the basis of a result of the measurement. The breakdown voltage of the SPAD 20 is a voltage between an anode and a cathode when the cathode voltage of the SPAD 20 has lowered to a bottom value.

For example, in a case where the breakdown voltage of the SPAD 20 is larger than expected, it takes time for the cathode voltage of the SPAD 20 to fall below threshold voltage of an inverter 28, and the ToF value becomes larger. Thus, in a case where the breakdown voltage of the SPAD 20 is larger than expected, it is desirable to further decrease the anode voltage and lower the cathode voltage. Thus, a voltage control unit 5 controls the bias voltage to be supplied to the anodes of the SPADs 20 in the first to third pixels 11a, 11b, and 11c on the basis of the breakdown voltage detected by the VBD monitor 31.

The thermometer 32 measures the temperature around the ranging device 1 according to the second embodiment. When the temperature rises, the cathode voltage of the SPADS 20 may, for example, rise. When the cathode voltage rises, it takes time for the cathode voltage to fall below the threshold voltage of the inverter 28, and the ToF value becomes larger. Thus, in a case where the temperature is high, it is desirable to further decrease the anode voltage. Thus, on the basis of the temperature measured by the thermometer 32, the voltage control unit 5 controls the bias voltage to be supplied to the anodes of the SPADs 20 in the first to third pixels 11a, 11b, and 11c.

The selector 33 selects any one from a ToF value detected by a peak detection unit 17, the breakdown voltage of the SPAD 20 in the second pixel 11b detected by the VBD monitor 31, or the temperature measured by the thermometer 32, and supplies the selected one to the voltage control unit 5. The order of selection by the selector 33 is optional.

The voltage control unit 5 generates a bias voltage corresponding to the ToF value detected by the peak detection unit 17, the breakdown voltage of the SPAD 20 in the second pixel 11b detected by the VBD monitor 31, or the temperature measured by the thermometer 32, whichever has been selected by the selector 33.

The voltage control unit 5 in FIG. 8 has a function (first control unit) of controlling the bias voltage to be supplied to the anodes or the cathodes of the SPADs 20 of the first pixel 11a and the second pixel 11b on the basis of the breakdown voltage monitored by the VBD monitor 31 and the temperature measured by the thermometer 32, and a function (second control unit) of controlling the bias voltage to be supplied to the anodes or the cathodes of the SPADs 20 of the first pixel 11a and the second pixel 11b on the basis of the ToF value detected by the peak detection unit 17 after the control by the first control unit has been performed.

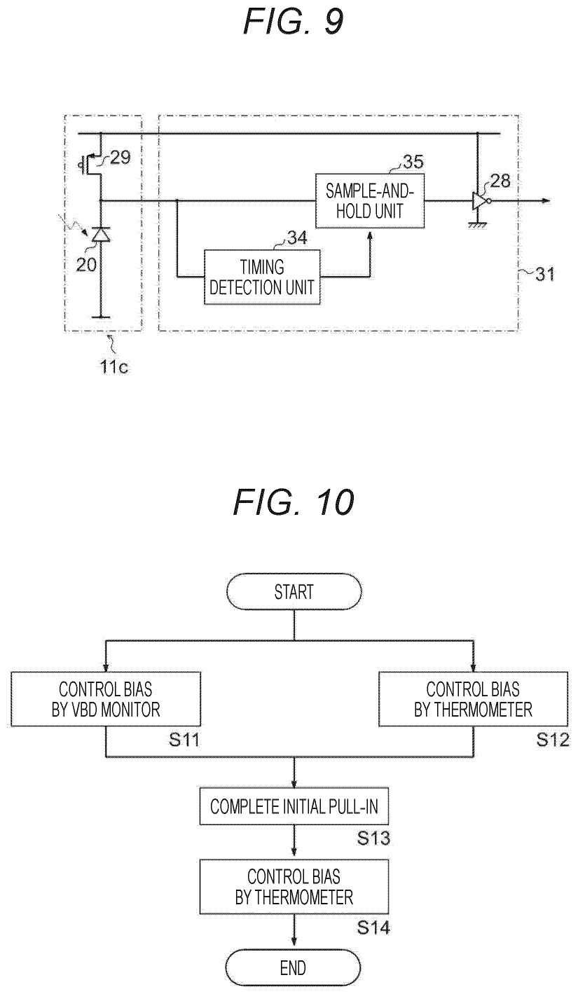

FIG. 9 is a block diagram illustrating an internal configuration of the VBD monitor 31. The VBD monitor 31 in FIG. 9 has a timing detection unit 34 and a sample-and-hold unit 35.

The timing detection unit 34 monitors the cathode voltage of the SPAD 20 in the third pixel 11c, and detects a timing at which a predetermined time has elapsed since the cathode voltage started to decrease. The sample-and-hold unit 35 holds the cathode voltage at the timing of detection by the timing detection unit 34. The cathode voltage that has been held is subjected to A/D conversion, for example, and input to the selector 33.

FIG. 10 is a flowchart illustrating a processing operation of the ranging device 1 according to the second embodiment. The processing operation of the flowchart in FIG. 10 is continuously executed while the ranging device 1 is ON.

First, controlling of the bias voltage by the breakdown voltage of the SPAD 20 in the third pixel 11c detected by the VBD monitor 31 (step S11) and controlling of the bias voltage by the temperature measured by the thermometer 32 (step S12) are executed in an optional order, the order being switched by the selector 33.

In the present specification, the controlling of the bias voltage in steps S11 and S12 is referred to as initial pull-in processing. When the initial pull-in processing in steps S11 and S12 ends (step S13), next, controlling of the bias voltage by the ToF value is performed (step S14). In step S14, the processing of steps S1 to S5 in FIG. 5 is performed.

The processing of step S14 may be continuously performed while the ranging device 1 is performing a ranging operation. On the other hand, the controlling of the bias voltage by the VBD monitor 31 and the controlling of the bias voltage by the thermometer 32 may be performed only immediately after the ranging device 1 is powered on or immediately after a reset operation of the ranging device 1. Alternatively, the processing of steps S11 and S12 may be repeatedly performed on a regular basis or on an irregular basis.

FIGS. 8 to 10 illustrate an example in which the controlling of the bias voltage by the VBD monitor 31 and the controlling of the bias voltage by the thermometer 32 are executed in an optional order, the order being switched by the selector 33, but it is also possible to perform only either the controlling of the bias voltage by the VBD monitor 31 or the controlling of the bias voltage by the thermometer 32.

As described above, in the second embodiment, at least one of the controlling of the bias voltage by the VBD monitor 31 or the controlling of the bias voltage by the thermometer 32 is performed in addition to the controlling of the bias voltage by the ToF value, so that the ranging accuracy can be further improved.

### Third Embodiment

When extremely strong ambient light is incident on a pixel array unit 11, the number of Rx pulse signals per unit time detected by an SPAD 20 in a first pixel 11a may significantly increase. An excessive increase in the number of Rx pulse signals per unit time results in an increase in processing load on a signal processing unit 23, and this causes a malfunction. Furthermore, this also causes an increase in power consumption. Thus, a ranging device 1 according to a third embodiment is characterized in that a function of controlling a bias voltage in accordance with the number of Rx pulse signals per unit time has been added to the ranging device 1 according to the first embodiment.

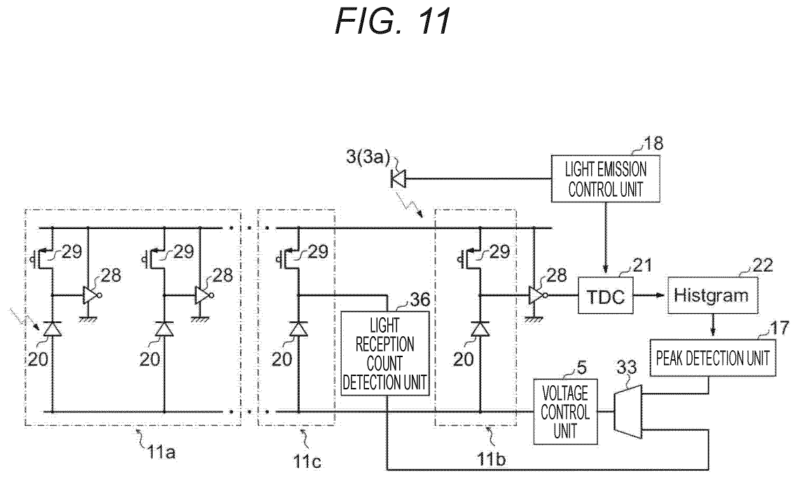

FIG. 11 is a detailed block diagram of a main portion in the ranging device 1 according to the first embodiment. The ranging device 1 in FIG. 11 includes a light reception count detection unit (second detection unit) 36 and a selector 33, in addition to the configuration in FIG. 7.

The light reception count detection unit 36 detects the number of Rx pulse signals per unit time. The light reception count detection unit 36 receives input of voltage signals output from each SPAD 20 in the first pixel 11a. The light reception count detection unit 36 detects the number of Rx pulse signals per unit time by counting the number of voltage signals, among these voltage signals, in which a cathode voltage level has reached a bottom value.

The selector 33 selects any one from the number of Rx pulse signals per unit time detected by the light reception count detection unit 36 or a peak position detected by the peak detection unit 17, and transmits the selected one to a voltage control unit 5. In a case where the selector 33 has selected the number of Rx pulse signals per unit time, the voltage control unit 5 controls the bias voltage of each SPAD 20 in the first pixel 11a and a second pixel 11b on the basis of the number of Rx pulse signals per unit time. For example, in a case where the number of Rx pulse signals per unit time is compared with a reference number prepared in advance and is larger than the reference number, it is determined that the ambient light is too strong, and the anode voltage of the SPAD 20 is increased. With this arrangement, the reverse bias voltage between an anode and a cathode of the SPAD 20 decreases, and the sensitivity of the SPAD 20 decreases.

On the other hand, in a case where the selector 33 has selected the peak position detected by the peak detection unit 17, the voltage control unit 5 controls the bias voltage in a procedure similar to that of the processing of steps S4 and S5 in FIG. 5.

Controlling of the bias voltage by the number of Rx pulse signals per unit time and controlling of the bias voltage by a ToF value may be repeatedly executed on a regular basis or on an irregular basis.

Note that the second embodiment and the third embodiment may be combined. In this case, the selector 33 optionally selects any one from the breakdown voltage detected by the VBD monitor 31, information regarding the temperature measured by the thermometer 32, the number of Rx pulse signals per unit time detected by the light reception count detection unit 36, or the peak position detected by the peak detection unit 17, and transmits the selected one to the voltage control unit 5.

As described above, in the third embodiment, not only the controlling of the bias voltage by the ToF value but also the controlling of the bias voltage by the number of Rx pulse signals per unit time are performed, so that the operation of the ranging device 1 can be stabilized and the increase in power consumption can be suppressed.

### One Modification of First to Third Embodiments

While the above-described first to third embodiments show examples in which the anode voltage of the SPAD 20 is controlled by the bias voltage output from the voltage control unit 5 and a voltage signal corresponding to an Rx pulse signal is output from the cathode side, it is also possible that the cathode voltage of the SPAD 20 is controlled by the bias voltage output from the voltage control unit 5 and a voltage signal corresponding to an Rx pulse signal is output from the anode side.

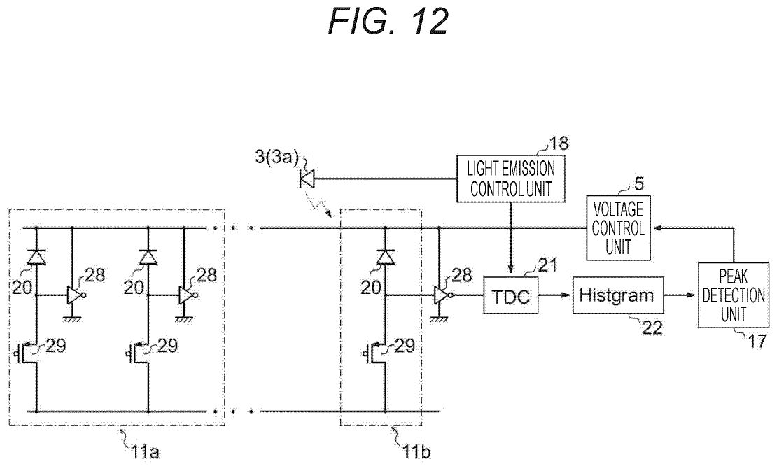

FIG. 12 is a block diagram in which a connection relationship between the anode and the cathode of the SPAD 20 in FIG. 7 is reversed. The bias voltage output from the voltage control unit 5 is supplied to the cathodes of the SPADs 20 in the first pixel 11a and the cathode of the SPAD 20 in the second pixel 11b in FIG. 12. The anode of the SPAD 20 in the first pixel 11a is connected with an inverter 28 and a constant current source 29. Furthermore, the anode of the SPAD 20 in the second pixel 11b is connected with an inverter 28 and a constant current source 29. The anode voltage of each SPAD 20 increases when an Rx pulse signal or a Tx pulse signal is received, and an output logic of the inverter 28 is inverted when the anode voltage exceeds the threshold voltage of the inverter 28.

As described above, the connection relationship between the anode and the cathode of the SPAD 20 in the first to third embodiments can be reversed.

### Application Example

The technology according to the present disclosure can be applied to various products. For example, the technology according to the present disclosure may also be implemented as a device mounted on any kind of mobile body such as an automobile, an electric automobile, a hybrid electric automobile, a motorcycle, a bicycle, a personal mobility, an airplane, a drone, a ship, a robot, a construction machine, or an agricultural machine (tractor).

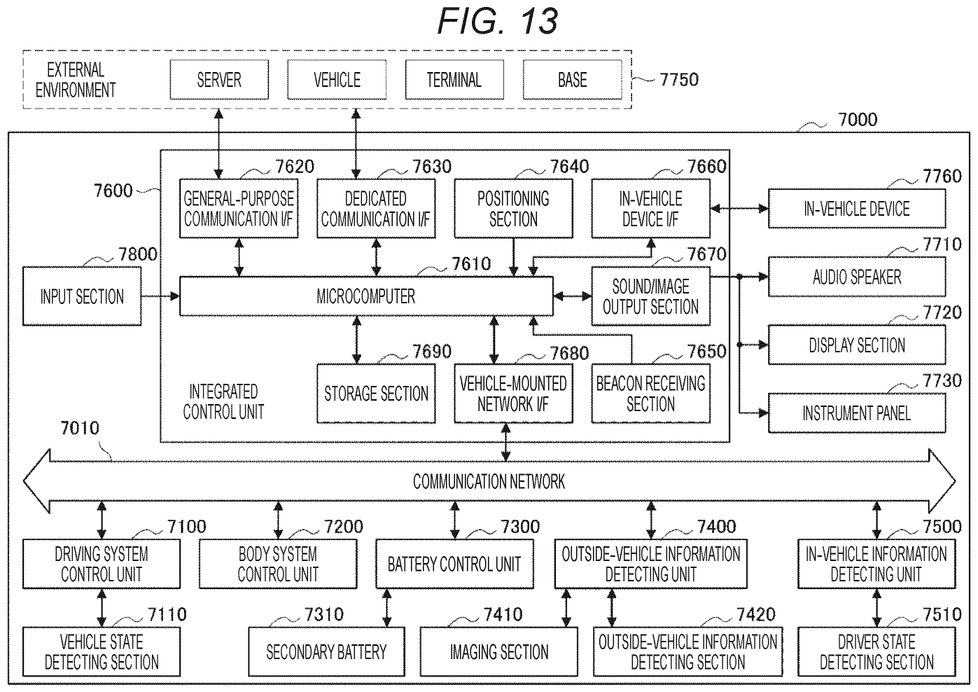

FIG. 13 is a block diagram illustrating a schematic configuration example of a vehicle control system 7000, which is an example of a mobile body control system to which the technology according to the present disclosure may be applied. The vehicle control system 7000 includes a plurality of electronic control units connected to each other via a communication network 7010. In the example illustrated in FIG. 13, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. In FIG. 13, a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690 are illustrated as a functional configuration of the integrated control unit 7600. The other control units similarly include a microcomputer, a communication I/F, a storage section, and the like,

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

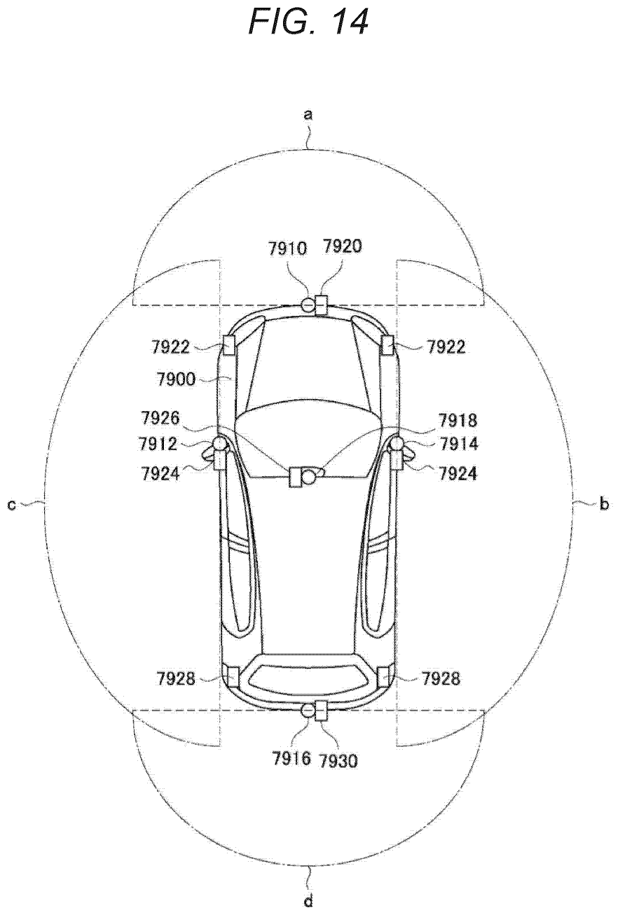

Here, FIG. 14 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 14 illustrates an example of an imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 13, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example in FIG. 13, an audio speaker 7710, a display section 7720, and an instrument panel 7730 are illustrated as output devices. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that, in the example illustrated in FIG. 13, at least two control units connected to each other via the communication network 7010 may be integrated as one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for implementing each function of the ranging device 1 according to the present embodiment described with reference to FIG. 1 and the like can be implemented in any of the control units or the like. Furthermore, a computer-readable recording medium in which such a computer program is stored can be provided. The recording medium is, for example, a magnetic disk, an optical disk, a magneto-optical disk, a flash memory, or the like. Furthermore, the computer program described above may be distributed via, for example, a network without using a recording medium.

In the vehicle control system 7000 described above, the ranging device 1 according to the present embodiment described with reference to FIG. 1 and the like can be applied to the integrated control unit 7600 of the application example illustrated in FIG. 13.

Furthermore, at least some of the components of the ranging device 1 described with reference to FIG. 1 and the like may be implemented in a module (e.g., an integrated circuit module constituted by one die) for the integrated control unit 7600 illustrated in FIG. 13. Alternatively, the ranging device 1 described with reference to FIG. 1 may be implemented by a plurality of control units of the vehicle control system 7000 illustrated in FIG. 13.

Note that the present technology can have the following configurations.
(1) A ranging device including:
a second pixel that is provided separately from a first pixel that performs ranging;
a first detection unit that detects a time of flight (ToF) value based on light reception time of incident light incident on the second pixel; and
a control unit that controls a bias voltage to be applied to the first pixel and the second pixel on the basis of the ToF value detected by the first detection unit.
(2) The ranging device according to (1), in which the first detection unit detects the ToF value on the basis of a time difference between the light reception time of the incident light incident on the second pixel and time at which a light emitting unit emitted a light signal.
(3) The ranging device according to (1) or (2), in which
the first pixel receives a reflected light signal obtained by causing a light signal emitted from a light emitting unit to be reflected by an object, and
the second pixel directly receives the light signal emitted from the light emitting unit.
(4) The ranging device according to any one of (1) to (3), in which
the first pixel has a first photodiode that outputs a voltage signal corresponding to incident light,
the second pixel has a second photodiode that outputs a voltage signal corresponding to incident light, and
the bias voltage is a voltage to be supplied to anode pressures or cathodes of the first photodiode and the second photodiode.
(5) The ranging device according to (4), in which the first photodiode and the second photodiode output the voltage signals from the cathodes in a case where the bias voltage is supplied to the anodes, and output the voltage signals from the anodes in a case where the bias voltage is supplied to the cathodes.
(6) The ranging device according to (4) or (5), in which
the first detection unit detects the ToF value based on the light reception time of the incident light by the second photodiode, and
the control unit controls an anode voltage or a cathode voltage of the first photodiode and the second photodiode on the basis of the ToF value detected by the first detection unit.
(7) The ranging device according to (6), in which the first detection unit detects the ToF value on the basis of a timing at which a voltage level of the voltage signal output from the anode or the cathode of the second photodiode intersects with a predetermined threshold.
(8) The ranging device according to any one of (4) to (7), in which the control unit controls the bias voltage to be supplied to the anodes or the cathodes of the first photodiode and the second photodiode in such a way that the ToF value based on the light reception time of the incident light by the second photodiode detected by the first detection unit becomes constant.
(9) The ranging device according to any one of (4) to (8), in which the control unit causes reverse voltages between the anodes and the cathodes of the first photodiode and the second photodiode to become larger in a case where the ToF value detected by the first detection unit is longer than a predetermined reference value.
(10) The ranging device according to any one of (4) to (9), further including:
a time-to-digital converter that generates digital signals corresponding to timings at which the voltage signals are output from the first photodiode and the second photodiode; and
a histogram generator that generates a histogram representing a frequency distribution of the light reception time of the incident light on the basis of the digital signal,
in which the first detection unit detects a peak position of the histogram based on the incident light of the second photodiode.
(11) The ranging device according to (10), further including a distance measurement unit that measures a distance to an object on the basis of the peak position of the histogram based on the incident light of the first photodiode.
(12) The ranging device according to any one of (4) to (11), further including:
a third pixel that is provided separately from the first pixel and the second pixel; and
a voltage monitoring unit that monitors a breakdown voltage of a third photodiode in the third pixel,
in which the control unit controls an anode voltage or a cathode voltage of the first photodiode, the second photodiode, and the third photodiode on the basis of the ToF value detected by the first detection unit and the breakdown voltage monitored by the voltage monitoring unit.
(13) The ranging device according to any one of (4) to (11), further including:
a temperature measuring instrument that measures an ambient temperature,
in which the control unit controls an anode voltage or a cathode voltage of the first photodiode and the second photodiode on the basis of the ToF value detected by the first detection unit and the temperature measured by the temperature measuring instrument.
(14) The ranging device according to any one of (4) to (11), further including:
a third pixel that is provided separately from the first pixel and the second pixel;
a voltage monitoring unit that monitors a breakdown voltage of a third photodiode in the third pixel; and
a temperature measuring instrument that measures an ambient temperature,
in which the control unit has:
a first control unit that controls the bias voltage to be supplied to the anodes or the cathodes of the first photodiode and the second photodiode on the basis of the breakdown voltage monitored by the voltage monitoring unit and the temperature measured by the temperature measuring instrument; and
a second control unit that controls the bias voltage to be supplied to the anodes or the cathodes of the first photodiode and the second photodiode on the basis of the ToF value detected by the first detection unit after the controlling by the first control unit.
(15) The ranging device according to any one of (4) to (11), further including:
a second detection unit that detects the number of light receiving pulses per unit time in the first pixel,
in which the control unit controls an anode voltage or a cathode voltage of the first photodiode and the second photodiode on the basis of the ToF value detected by the first detection unit and the number of light receiving pulses per unit time detected by the second detection unit.
(16) The ranging device according to (15), in which the control unit causes reverse voltages between the anodes and the cathodes of the first photodiode and the second photodiode to become smaller in a case where the number of light receiving pulses detected by the second detection unit is larger than a predetermined reference number of pulses.
(17) The ranging device according to any one of (4) to (16), further including:
a light emitting unit that emits a light signal,
in which the first photodiode in the first pixel receives the incident light based on a reflected light signal from an object irradiated with the light signal.
(18) The ranging device according to (17), in which
the second pixel is arranged away from the first pixel, and
a light shielding member is included, the light shielding member being arranged around the second photodiode in such a way that the light signal to be incident on the second photodiode is not incident on the first photodiode.
(19) The ranging device according to (17), further including:
a pixel array unit that has a plurality of pixels, each of the pixels having a photodiode,
in which some of the pixels in the pixel array unit are used as the first pixel,
at least some of the pixels other than the some of the pixels in the pixel array unit are used as the second pixel, and
a light shielding member is included, the light shielding member being arranged along a boundary region between the first pixel and the second pixel in the pixel array unit, and being arranged around the second photodiode in such a way that the light signal to be incident on the second photodiode is not incident on the first photodiode.
(20) The ranging device according to any one of (17) to (19), in which the light signal emitted from the light emitting unit is radiated in a direction toward the object, and is also radiated in a direction toward the second pixel.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1 Ranging device
2 Ranging system
3 Light emitting unit
3a Light emitting element
4 Overall control unit
5 Voltage control unit
11 Pixel array unit
11a Third pixel
11a First pixel
11b Second pixel
11c Third pixel
12 Ranging processing unit
13 Output unit
14 Drive circuit
15 Light emission timing control unit
16 Ranging control unit
17 Peak detection unit (first detection unit)
18 Control unit
19 Clock generation unit
20 Light receiving element
22 Histogram generation unit
23 Signal processing unit
23a Distance computation unit
24 First chip
25 Second chip
26 Light shielding member
27 Support substrate
28 Inverter
29 Constant current source
31 VBD monitor (voltage monitoring unit)
32 Thermometer (temperature measuring instrument)
33 Selector
34 Timing detection unit
35 Sample-and-hold unit
36 Light reception count detection unit (second detection unit)

1. A ranging device comprising:
a second pixel that is provided separately from a first pixel that performs ranging;
a first detection unit that detects a time of flight (ToF) value based on light reception time of incident light incident on the second pixel; and
a control unit that controls a bias voltage to be applied to the first pixel and the second pixel on a basis of the ToF value detected by the first detection unit.

2. The ranging device according to claim 1, wherein the first detection unit detects the ToF value on a basis of a time difference between the light reception time of the incident light incident on the second pixel and time at which a light emitting unit emitted a light signal.

3. The ranging device according to claim 1, wherein
the first pixel receives a reflected light signal obtained by causing a light signal emitted from a light emitting unit to be reflected by an object, and
the second pixel directly receives the light signal emitted from the light emitting unit.

4. The ranging device according to claim 1, wherein
the first pixel has a first photodiode that outputs a voltage signal corresponding to incident light,
the second pixel has a second photodiode that outputs a voltage signal corresponding to incident light, and
the bias voltage is a voltage to be supplied to anode pressures or cathodes of the first photodiode and the second photodiode.

5. The ranging device according to claim 4, wherein the first photodiode and the second photodiode output the voltage signals from the cathodes in a case where the bias voltage is supplied to the anodes, and output the voltage signals from the anodes in a case where the bias voltage is supplied to the cathodes.

6. The ranging device according to claim 4, wherein
the first detection unit detects the ToF value based on the light reception time of the incident light by the second photodiode, and
the control unit controls an anode voltage or a cathode voltage of the first photodiode and the second photodiode on a basis of the ToF value detected by the first detection unit.

7. The ranging device according to claim 6, wherein the first detection unit detects the ToF value on a basis of a timing at which a voltage level of the voltage signal output from the anode or the cathode of the second photodiode intersects with a predetermined threshold.

8. The ranging device according to claim 4, wherein the control unit controls the bias voltage to be supplied to the anodes or the cathodes of the first photodiode and the second photodiode in such a way that the ToF value based on the light reception time of the incident light by the second photodiode detected by the first detection unit becomes constant.

9. The ranging device according to claim 4, wherein the control unit causes reverse voltages between the anodes and the cathodes of the first photodiode and the second photodiode to become larger in a case where the ToF value detected by the first detection unit is longer than a predetermined reference value.

10. The ranging device according to claim 4, further comprising:
a time-to-digital converter that generates digital signals corresponding to timings at which the voltage signals are output from the first photodiode and the second photodiode; and
a histogram generator that generates a histogram representing a frequency distribution of the light reception time of the incident light on a basis of the digital signal,
wherein the first detection unit detects a peak position of the histogram based on the incident light of the second photodiode.

11. The ranging device according to claim 10, further comprising a distance measurement unit that measures a distance to an object on a basis of the peak position of the histogram based on the incident light of the first photodiode.

12. The ranging device according to claim 4, further comprising:
a third pixel that is provided separately from the first pixel and the second pixel; and
a voltage monitoring unit that monitors a breakdown voltage of a third photodiode in the third pixel,
wherein the control unit controls an anode voltage or a cathode voltage of the first photodiode, the second photodiode, and the third photodiode on a basis of the ToF value detected by the first detection unit and the breakdown voltage monitored by the voltage monitoring unit.

13. The ranging device according to claim 4, further comprising:
a temperature measuring instrument that measures an ambient temperature,
wherein the control unit controls an anode voltage or a cathode voltage of the first photodiode and the second photodiode on a basis of the ToF value detected by the first detection unit and the temperature measured by the temperature measuring instrument.

14. The ranging device according to claim 4, further comprising:
a third pixel that is provided separately from the first pixel and the second pixel;
a voltage monitoring unit that monitors a breakdown voltage of a third photodiode in the third pixel; and
a temperature measuring instrument that measures an ambient temperature,
wherein the control unit has:
a first control unit that controls the bias voltage to be supplied to the anodes or the cathodes of the first photodiode and the second photodiode on a basis of the breakdown voltage monitored by the voltage monitoring unit and the temperature measured by the temperature measuring instrument; and
a second control unit that controls the bias voltage to be supplied to the anodes or the cathodes of the first photodiode and the second photodiode on a basis of the ToF value detected by the first detection unit after the controlling by the first control unit.

15. The ranging device according to claim 4, further comprising:
a second detection unit that detects the number of light receiving pulses per unit time in the first pixel,
wherein the control unit controls an anode voltage or a cathode voltage of the first photodiode and the second photodiode on a basis of the ToF value detected by the first detection unit and the number of light receiving pulses per unit time detected by the second detection unit.

16. The ranging device according to claim 15, wherein the control unit causes reverse voltages between the anodes and the cathodes of the first photodiode and the second photodiode to become smaller in a case where the number of light receiving pulses detected by the second detection unit is larger than a predetermined reference number of pulses.

17. The ranging device according to claim 4, further comprising:
a light emitting unit that emits a light signal,
wherein the first photodiode in the first pixel receives the incident light based on a reflected light signal from an object irradiated with the light signal.

18. The ranging device according to claim 17, wherein
the second pixel is arranged away from the first pixel, and
a light shielding member is included, the light shielding member being arranged around the second photodiode in such a way that the light signal to be incident on the second photodiode is not incident on the first photodiode.

19. The ranging device according to claim 17, further comprising:
a pixel array unit that has a plurality of pixels, each of the pixels having a photodiode,
wherein some of the pixels in the pixel array unit are used as the first pixel,
at least some of the pixels other than the some of the pixels in the pixel array unit are used as the second pixel, and
a light shielding member is included, the light shielding member being arranged along a boundary region between the first pixel and the second pixel in the pixel array unit, and being arranged around the second photodiode in such a way that the light signal to be incident on the second photodiode is not incident on the first photodiode.

20. The ranging device according to claim 17, wherein the light signal emitted from the light emitting unit is radiated in a direction toward the object, and is also radiated in a direction toward the second pixel.
